(19) United States
(12) Patent Application Publication
(10) Pub. No.: US 2026/0074692 A1
(43) Pub. Date: Mar. 12, 2026

(54) POWER GATING CIRCUIT AND SEMICONDUCTOR APPARATUS INCLUDING THE POWER GATING CIRCUIT

(71) Applicant: SK hynix Inc., Icheon-si Gyeonggi-do (KR)

(72) Inventor: Yun Suk HONG, Icheon-si Gyeonggi-do (KR)

(73) Assignee: SK hynix Inc., Icheon-si Gyeonggi-do (KR)

(21) Appl. No.: 19/037,916

(22) Filed: Jan. 27, 2025

(30) Foreign Application Priority Data
Sep. 11, 2024 (KR) 10-2024-0124138

(51) Int. Cl. H03K 17/687; G11C 5/14; G11C 7/12

(52) U.S. Cl. CPC H03K 17/687; G11C 5/147; G11C 7/12

(57) ABSTRACT

A power gating circuit includes a power gating switch and a switching circuit. The power gating switch is coupled to a function block and operates in response to a voltage level of a first node. The switching circuit turns off the power gating switch by discharging the first node to a second driving voltage level during a first time period after blocking a first driving voltage from being applied to the first node in accordance with a plurality of control signals, and applying a third driving voltage to the first node during a second time period after the first time period.

### CROSS-REFERENCES TO RELATED APPLICATION

The present application claims priority under 35 U.S.C. § 119(a) to Korean application number 10-2024-0124138 filed on Sep. 11, 2024, in the Korean Intellectual Property Office, which application is incorporated herein by reference in its entirety.

### BACKGROUND

### 1. Technical Field

Various embodiments generally relate to a semiconductor circuit, and, more particularly, to a power gating circuit and a semiconductor apparatus including the power gating circuit

### 2. Related Art

In recent years, electronic devices, such as portable electronics, have become smaller and lighter, while the number of function blocks embedded in them has continued to increase.

In particular, the portable electronics operate on a limited power source, so it is necessary to reduce the power unnecessarily consumed by function blocks. For this purpose, power gating technology is applied.

### SUMMARY

In an embodiment, a power gating circuit may include a power gating switch and a switching circuit. The power gating switch may be configured to be coupled to a function block and may be configured to operate in response to a voltage level of a first node. The switching circuit may be configured to turn off the power gating switch by discharging the first node to a second driving voltage level during a first time period after blocking a first driving voltage from being applied to the first node in accordance with a plurality of control signals, and applying a third driving voltage to the first node during a second time period after the first time period.

In an embodiment, a power gating circuit may include a power gating switch, a first transistor, a second transistor, and a third transistor. The power gating switch may be configured to be coupled to a function block and may be configured to operate in response to a voltage level of a first node. The first transistor may be configured to receive a first driving voltage at its source terminal, couple its drain terminal to the first node, and operate according to a first control signal. The second transistor may be configured to receive a second driving voltage at its source terminal, couple its drain terminal to the first node, and operate according to a second control signal. The third transistor may be configured to receive a third driving voltage at its source terminal, couple its drain terminal to the drain terminal of the first transistor, and operate according to a third control signal.

In an embodiment, a semiconductor apparatus may include a plurality of memory banks, a plurality of column driving regions, and a voltage generation circuit. The plurality of column driving regions may be configured to be coupled to the plurality of memory banks, may be configured to receive a first driving voltage and a third driving voltage, and may be configured to include circuits associated with column operations of each of the plurality of memory banks. The voltage generation circuit may be configured to generate the third driving voltage in response to a power source that is external to the semiconductor apparatus, and may be configured to provide the third driving voltage to each of the plurality of column driving regions. Each of the plurality of column driving regions may include at least one function block and a power gating circuit coupled to the function block. The power gating circuit may include: a power gating switch configured to be coupled to the function block and configured to operate in response to a voltage level of a first node; and a switching circuit configured to turn off the power gating switch by discharging the first node to a second driving voltage level during a first time period after blocking the first driving voltage from being applied to the first node in accordance with a plurality of control signals, and applying the third driving voltage to the first node during a second time period after the first time period.

### BRIEF DESCRIPTION OF THE DRAWINGS

FIG. 1 is a diagram illustrating a power gating circuit according to an embodiment of the present disclosure.

FIG. 2 is a diagram illustrating an operation of a power gating circuit according to an embodiment of the present disclosure.

FIG. 3 is a diagram illustrating a power gating circuit according to an embodiment of the present disclosure.

FIG. 4 is a diagram illustrating a switching circuit of FIG. 3.

FIG. 5 is a diagram illustrating a control circuit of FIG. 3.

FIG. 6 is a diagram illustrating an operation of a power gating circuit according to an embodiment of the present disclosure.

FIG. 7 is a diagram illustrating a semiconductor apparatus according to an embodiment of the present disclosure.

### DETAILED DESCRIPTION

Various embodiments of the present disclosure can reduce power consumption and operational errors, and thus improve operational reliability.

Hereinafter, embodiments of the present disclosure will be described in more detail with reference to the accompanying drawings.

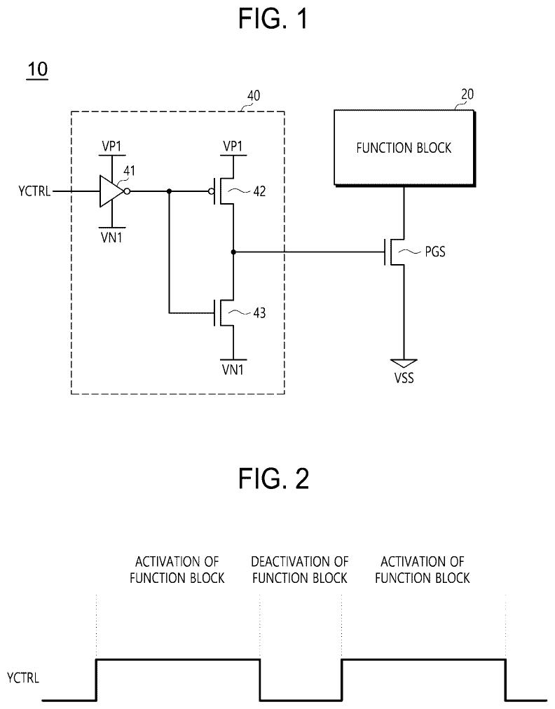

FIG. 1 is a diagram illustrating a power gating circuit 10 according to an embodiment of the present disclosure, and FIG. 2 is a diagram illustrating an operation of the power gating circuit 10 according to an embodiment of the present disclosure.

Referring to FIG. 1, the power gating circuit 10 may include a power gating switch PGS and a switching circuit 40.

The power gating switch PGS may include a transistor having a source terminal coupled to a ground terminal and a drain terminal coupled to at least one function block 20. The function block 20 may be a circuit block designed to perform a defined function and may include a plurality of logic gates. The plurality of logic gates may each include at least one transistor, and a source terminal or a drain terminal of each transistor may be connected to the drain terminal of the power gating switch PGS.

The switching circuit 40 may turn on or turn off the power gating switch PGS in response to a control signal YCTRL. The switching circuit 40 may turn the power gating switch PGS on when the control signal YCTRL is at a high level, and the switching circuit 40 may turn the power gating switch PGS off when the control signal YCTRL is at a low level.

The switching circuit 40 may include a logic gate 41, a first transistor 42, and a second transistor 43. The logic gate 41 may invert the control signal YCTRL and may output an inverted control signal. A first driving voltage VP1 may be applied to the logic gate 41 as a pull-up power source, and a third driving voltage VN1 may be applied to the logic gate 41 as a pull-down power source. The first driving voltage VP1 may be a positive voltage, and the third driving voltage VN1 may be a negative voltage. The first driving voltage VP1 and the third driving voltage VN1 may be provided through an internal power circuit of a device including the power gating circuit 10 or may be provided externally. The first driving voltage VP1 may be applied to the first transistor 42 at a source terminal, and an output of the logic gate 41 may be applied to the first transistor 42 at a gate terminal. The third driving voltage VN1 may be applied to the second transistor 43 at a source terminal, and the output of the logic gate 41 may be applied to the second transistor 43 at a gate terminal. A drain terminal of the second transistor 43 may be coupled to a drain terminal of the first transistor 42.

Referring to FIG. 2, the control signal YCTRL may be transitioned to a high level to coincide with the activation timing of the function block 20, and the control signal YCTRL may be transitioned to a low level to coincide with the deactivation timing of the function block 20. Assuming that the device including the power gating circuit 10 is a semiconductor memory apparatus, the control signal YCTRL may be a signal generated to match the timing of a column operation of each of a read operation and a write operation of the semiconductor memory apparatus.

When the control signal YCTRL is at a high level, the switching circuit 40 may turn on the power gating switch PGS by applying the first driving voltage VP1 to the gate terminal of the power gating switch PGS. When the control signal YCTRL is at a low level, the switching circuit 40 may turn the power gating switch PGS off by applying the third driving voltage VN1 to the gate terminal of the power gating switch PGS. As the power gating switch PGS is turned on, current path of the function block 20 may be activated, and the function block 20 may perform its predetermined function accordingly. As the power gating switch PGS is turned off, the current path of the function block 20 may be deactivated, and the function block 20 may be put into a standby state accordingly. The third driving voltage VN1 may be a negative voltage, that is, a voltage level below a ground voltage level, which is a voltage level of the source terminal of the power gating switch PGS. Thus, when the function block 20 is in the standby state, the leakage current through the power gating switch PGS in the function block 20 can be minimized.

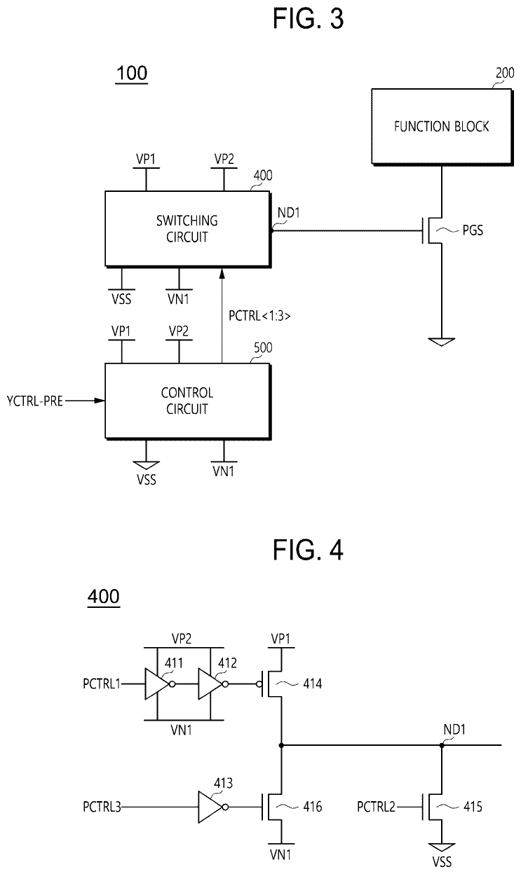

FIG. 3 is a diagram illustrating a power gating circuit 100 according to an embodiment of the present disclosure.

Referring to FIG. 3, the power gating circuit 100 may include a power gating switch PGS, a switching circuit 400, and a control circuit 500.

The power gating switch PGS may include a transistor having a source terminal coupled to a ground terminal and a drain terminal coupled to at least one function block 200. The power gating switch PGS may operate in response to a voltage level of a first node ND1. The function block 200 may be a circuit block designed to perform a defined function and may include a plurality of logic gates. The plurality of logic gates may each include at least one transistor, and a source terminal or a drain terminal of each transistor may be connected to the drain terminal of the power gating switch PGS. The power gating switch PGS may be commonly connected to a plurality of transistors in the function block 200 and may be designed to have a higher driving capability than other devices to drive the plurality of transistors. Thus, the gate terminal of the power gating switch PGS may be designed to have a large line width compared to other devices and may necessarily have a high capacitance.

The switching circuit 400 may receive a first driving voltage VP1, a third driving voltage VN1, a second driving voltage VSS, a fourth driving voltage VP2, and a plurality of control signals PCTRL<1:3>, and its output terminal may be coupled to the first node ND1. The switching circuit 400 may turn on or turn off the power gating switch PGS by controlling a voltage level of the first node ND1 according to the plurality of control signals PCTRL<1:3>. The first driving voltage VP1 may be a positive voltage (e.g., 0.9 V), the second driving voltage VSS may be a ground voltage (e.g., 0 V), the third driving voltage VN1 may be a negative voltage (e.g., −0.3 V), and the fourth driving voltage VP2 may be a positive voltage (e.g., 1.1 V) that is at a higher voltage level than the first driving voltage VP1.

The switching circuit 400 may turn on the power gating switch PGS by applying the first driving voltage VP1 to the first node ND1 according to the plurality of control signals PCTRL<1:3>. When a first control signal PCTRL1 is at a low level, the switching circuit 400 may turn on the power gating switch PGS by applying the first driving voltage VP1 to the first node ND1.

The switching circuit 400 may turn off the power gating switch PGS by discharging the first node ND1 for a first time period after blocking the first driving voltage VP1 from being applied to the first node ND1 according to the plurality of control signals PCTRL<1:3> and by applying the third driving voltage VN1 to the first node ND1 for a second time period after the first time period. The switching circuit 400 may block the first driving voltage VP1 from being applied to the first node ND1 according to the first control signal PCTRL1, transition the first node ND1 to the second driving voltage level according to the second control signal PCTRL2 for a first time period after deactivating the first control signal PCTRL1, and apply the third driving voltage VN1 to the first node ND1 for a second time period after the first time period according to a third control signal PCTRL3.

The control circuit 500 may receive the first driving voltage VP1, the third driving voltage VN1, the second driving voltage VSS, the fourth driving voltage VP2, and a preliminary control signal YCTRL-PRE as inputs and may output the plurality of control signals PCTRL<1:3>. The preliminary control signal YCTRL-PRE may be a signal associated with a read operation and a write operation, such as a signal that is activated in response to a read command and a write command, respectively, and may be deactivated after a termination of the read operation in response to the read command and after a termination of the write operation in response to the write command.

FIG. 4 is a diagram illustrating the switching circuit 400 of FIG. 3.

Referring to FIG. 4, the switching circuit 400 may include a plurality of logic gates 411 to 413 and a plurality of transistors 414 to 416.

The first logic gate 411 may invert the first control signal PCTRL1 and may output an inverted first control signal. The second logic gate 412 may invert an output of the first logic gate 411. The third logic gate 413 may invert the third control signal PCTRL3. The first transistor 414 may include a source terminal to which the first driving voltage VP1 is applied, a gate terminal receiving an output of the second logic gate 412, and a drain terminal coupled to the first node ND1. The second transistor 415 may include a source terminal to which the second driving voltage VSS is applied, a gate terminal receiving the second control signal PCTRL2, and a drain terminal coupled to the first node ND1. The third transistor 416 may include a source terminal to which the third driving voltage VN1 is applied, a gate terminal receiving an output of the third logic gate 413, and a drain terminal coupled to the drain terminal of the first transistor 414.

The first logic gate 411 and the second logic gate 412 may operate by using the fourth driving voltage VP2 and the third driving voltage VN1 as power sources. While the first transistor 414 operates according to the first driving voltage VP1, the first logic gate 411 and the second logic gate 412 may operate according to the fourth driving voltage VP2, which has a higher voltage level compared to the first driving voltage VP1, to control the first transistor 414, thereby minimizing leakage current through the first transistor 414. The third transistor 416 may be designed to have a small driving force compared to the second transistor 415. As such, the third transistor 416 may be able to drive the first node ND1 down to a voltage level of the third driving voltage VN1 relatively slowly compared to the second transistor 415 driving the first node ND1 down to a voltage level of the second driving voltage VSS. As will be described further below, as the third transistor 416 slowly drops the first node ND1 to a voltage level of the third driving voltage VN1, the current consumption of a circuit generating the third driving voltage VN1 can be reduced.

Hereinafter, an operation of the switching circuit 400 will be described as follows.

During a period in which the first control signal PCTRL1 is at a low level, the first transistor 414 may be turned on to apply the first driving voltage VP1 to the first node ND1. As a voltage level of the first node ND1 rises to a voltage level of the first driving voltage VP1, the power gating switch PGS may be turned on, and as the power gating switch PGS is turned on, current path in the function block 200 may be activated so that the function block 200 may perform its predetermined function.

The power gating switch PGS may be turned off by turning off the first transistor 414 during a period in which the first control signal PCTRL1 is at a high level and by turning on the second transistor 415 during a period in which the second control signal PCTRL2 is at a high level, thereby applying the second driving voltage VSS to the first node ND1. As a voltage level of the first node ND1 drops to a voltage level of the second driving voltage VSS, the charge on the gate of the power gating switch PGS may be discharged to a voltage level of the second driving voltage VSS.

During a period in which the third control signal PCTRL3 is at a low level, the third transistor 416 may be turned on to apply the third driving voltage VN1 to the first node ND1, thereby causing a voltage level of the first node ND1 to drop to a voltage level of the third driving voltage VN1 that is lower than a voltage level of the second driving voltage VSS.

After fully discharging a voltage level of the gate of the power gating switch PGS to a voltage level of the second driving voltage VSS according to the first control signal PCTRL1 and the second control signal PCTRL2, the third control signal PCTRL3 may be applied to the gate terminal of the power gating switch PGS to deactivate the function block 200 by applying the third driving voltage VN1, which has a lower voltage level than the second driving voltage VSS. By applying the third driving voltage VN1, which has a lower voltage level than the second driving voltage VSS, to the gate terminal of the power gating switch PGS, the leakage current of the function block 200 can be minimized.

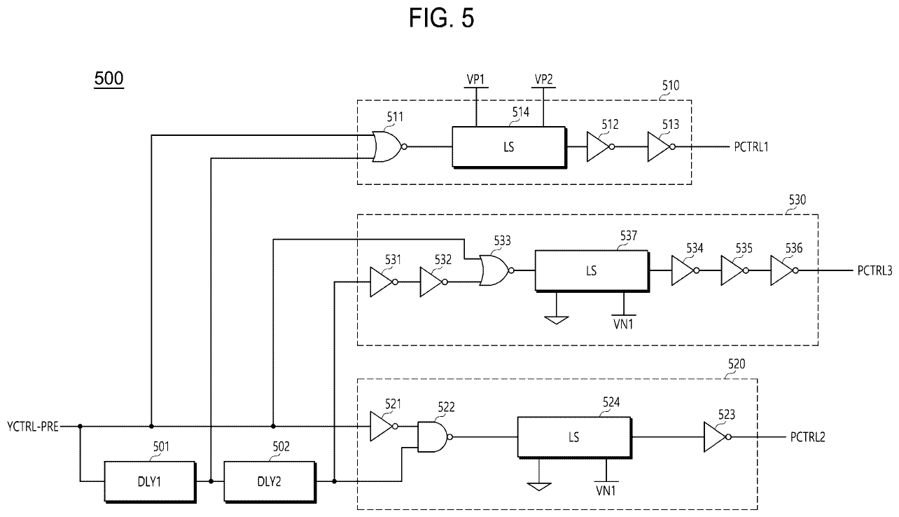

FIG. 5 is a diagram illustrating the control circuit 500 of FIG. 3.

Referring to FIG. 5, the control circuit 500 may include a plurality of delay circuits 501 and 502 and a plurality of signal generation circuits 510, 520, and 530.

The first delay circuit DLY1 501 may delay the preliminary control signal YCTRL-PRE by a setup time. The second delay circuit DLY2 502 may delay the preliminary control signal YCTRL-PRE by a setup time.

The first signal generation circuit 510 may receive the preliminary control signal YCTRL-PRE and an output of the first delay circuit 501 and may output the first control signal PCTRL1. The first signal generation circuit 510 may include a plurality of logic gates 511 to 513 and a level shifter (LS) 514. The first logic gate 511 may output a result from performing a NOR operation on the preliminary control signal YCTRL-PRE and the output of the first delay circuit 501. The level shifter 514 may change a pull-up level of an output signal of the first logic gate 511 to match the fourth driving voltage VP2. The second logic gate 512 may invert an output of the level shifter 514. The third logic gate 513 may output a signal that inverts an output of the second logic gate 512 as the first control signal PCTRL1. The first logic gate 511 may use the first driving voltage VP1 as a power source for a pull-up operation (hereinafter referred to as a pull-up power source) and may use the second driving voltage VSS as a power source for a pull-down operation (hereinafter referred to as a pull-down power source). The second logic gate 512 and the third logic gate 513 may use the fourth driving voltage VP2 as a pull-up power source and the second driving voltage VSS as a pull-down power source. Thus, the first control signal PCTRL1 can swing from a level of the second driving voltage VSS to the fourth driving voltage VP2 level.

The second signal generation circuit 520 may receive the preliminary control signal YCTRL-PRE and an output of the second delay circuit 502 and may output the second control signal PCTRL2. The second signal generation circuit 520 may include a plurality of logic gates 521 to 523 and a level shifter (LS) 524. The first logic gate 521 may invert the preliminary control signal YCTRL-PRE. The second logic gate 522 may output a result from performing a NAND operation on an output of the first logic gate 521 and the output of the second delay circuit 502. The level shifter 524 may change a swing level of an output signal of the second logic gate 522 to match the third driving voltage VN1. The third logic gate 523 may output a signal that inverts an output of the level shifter 524 as the second control signal PCTRL2. The first logic gate 521 and the second logic gate 522 may use the first driving voltage VP1 as a pull-up power source and may use the second driving voltage VSS as a pull-down power source. The third logic gate 523 may use the first driving voltage VP1 as a pull-up power source and may use the third driving voltage VN1 as a pull-down power source. Thus, the second control signal PCTRL2 can swing from the first driving voltage VP1 level to a level of the third driving voltage VN1.

The third signal generation circuit 530 may receive the preliminary control signal YCTRL-PRE and the output of the second delay circuit 502 and may output the third control signal PCTRL3. The third signal generation circuit 530 may include a plurality of logic gates 531 to 536 and a level shifter (LS) 537. The first logic gate 531 may invert the output of the second delay circuit 502. The second logic gate 532 may invert an output of the first logic gate 531. The third logic gate 533 may output a result from performing a NOR operation on the preliminary control signal YCTRL-PRE and an output of the second logic gate 532. The level shifter 537 may change a swing level of an output signal of the third logic gate 533 to match the third driving voltage VN1. The fourth logic gate 534 may invert an output of the level shifter 537. The fifth logic gate 535 may invert an output of the fourth logic gate 534. The sixth logic gate 536 may output a signal that inverts an output of the fifth logic gate 535 as the third control signal PCTRL3. The first logic gate 531, the second logic gate 532, and the third logic gate 533 may use the first driving voltage VP1 as a pull-up power source and may use the second driving voltage VSS as a pull-down power source. The fourth logic gate 534, the fifth logic gate 535, and the sixth logic gate 536 may use the first driving voltage VP1 as a pull-up power source and may use the third driving voltage VN1 as a pull-down power source. Thus, the third control signal PCTRL3 can swing from the first driving voltage VP1 level to a level of the third driving voltage VN1.

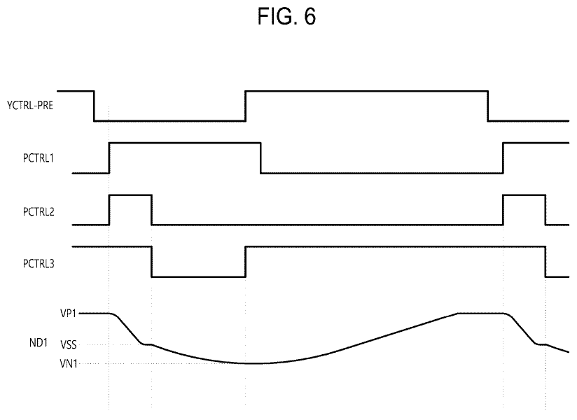

FIG. 6 is a diagram illustrating an operation of the power gating circuit 100 according to an embodiment of the present disclosure.

Referring to FIGS. 3 to 6, the power gating switch PGS may be turned on during a period in which the first control signal PCTRL1 is at a low level so that the function block 200 may perform a predetermined function.

After terminating a read operation or write operation, the preliminary control signal YCTRL-PRE may transition to a low level, and the first control signal PCTRL1 and the second control signal PCTRL2 may transition to a high level after a predetermined delay time.

As the first control signal PCTRL1 and the second control signal PCTRL2 transition to a high level, the power gating switch PGS may be turned off and the function block 200 may be deactivated.

The first driving voltage VP1 may be blocked from being applied to the power gating switch PGS during a period in which the first control signal PCTRL1 is at a high level, and the first node ND1 may be coupled to the ground terminal VSS during a period in which the second control signal PCTRL2 is at a high level. As a voltage level of the first node ND1 drops to a voltage level of the ground terminal VSS, a voltage level of a gate of the power gating switch PGS may be discharged to a voltage level of the second driving voltage VSS.

Subsequently, as the second control signal PCTRL2 transitions to a low level, the third control signal PCTRL3 may transition to a low level.

During a period in which the third control signal PCTRL3 is at a low level, the third driving voltage VN1 may be applied to the first node ND1 to drop a voltage level of the first node ND1 to a voltage level of the third driving voltage VN1 that is lower than a voltage level of the second driving voltage VSS.

After fully discharging a voltage level of the gate of the power gating switch PGS to a voltage level of the second driving voltage VSS according to the first control signal PCTRL1 and the second control signal PCTRL2, the third control signal PCTRL3 may be applied to the gate terminal of the power gating switch PGS to deactivate the function block 200 by applying the third driving voltage VN1, which has a lower voltage level than the second driving voltage VSS. By applying the third driving voltage VN1, which has a lower voltage level than a the second driving voltage VSS, to the gate terminal of the power gating switch PGS, the leakage current of the function block 200 can be minimized.

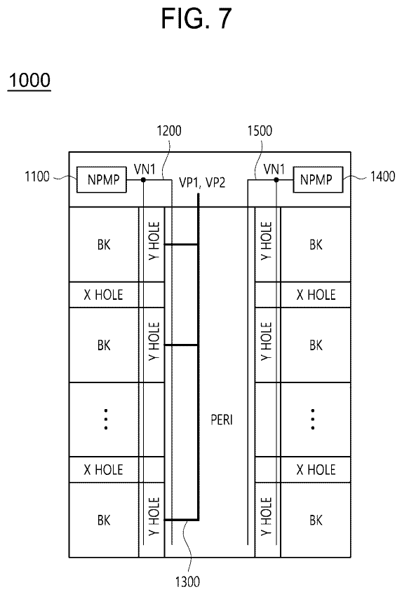

FIG. 7 is a diagram illustrating a semiconductor apparatus 1000 according to an embodiment of the present disclosure.

Referring to FIG. 7, the semiconductor apparatus 1000 may include a plurality of unit memory blocks, such as a plurality of memory banks BK, a peripheral circuit region PERI, a plurality of column driving regions YHOLE, a plurality of row driving regions XHOLE, negative voltage generation circuits (NPMP) 1100 and 1400, and power lines 1200, 1300, and 1500.

The plurality of memory banks BK may be disposed on either side or both sides of the peripheral circuit region PERI.

The peripheral circuit region PERI, the plurality of column driving regions YHOLE, and the plurality of row driving regions XHOLE may be associated with the plurality of memory banks BK. The peripheral circuit region PERI, the plurality of column driving regions YHOLE, and the plurality of row driving regions XHOLE may be provided with at least one of the first driving voltage VP1, the third driving voltage VN1, and the fourth driving voltage VP2.

The peripheral circuit region PERI may include data input and output related circuits that interact with the plurality of memory banks BK and devices external to the semiconductor apparatus 1000 and may include various circuits related thereto.

The plurality of column driving regions YHOLE may be disposed between each of the plurality of memory banks BK and the peripheral circuit region PERI. The plurality of column driving regions YHOLE may include circuits associated with column operations of each of the plurality of memory banks BK.

The plurality of row driving regions XHOLE may be disposed between the plurality of memory banks BK. The plurality of row driving regions XHOLEs may include circuits associated with row operations of each of the plurality of memory banks BK.

The negative voltage generation circuits 1100 and 1400 may receive power from a power source that is external to the semiconductor apparatus 1000 (hereinafter, external power source) and may perform pumping operations to generate the third driving voltage VN1. Each of the negative voltage generation circuits 1100 and 1400 may be disposed on each side of the peripheral circuit region PERI, respectively. The first negative voltage generation circuit 1100 may provide the third driving voltage VN1 to each of the corresponding column driving regions YHOLE disposed to the left of the peripheral circuit region PERI through the power line 1200. The second negative voltage generation circuit 1400 may provide the third driving voltage VN1 to each of the corresponding column driving regions YHOLE disposed to the right of the peripheral circuit region PERI through the power line 1500.

The first driving voltage VP1 and the fourth driving voltage VP2 generated by power circuits (not shown) may be provided, in common, to the peripheral circuit region PERI and the plurality of column driving regions YHOLE through the power line 1300.

The power gating circuit 100, described with reference to FIGS. 3 to 6, may be disposed in each of the peripheral circuit region PERI and the plurality of column driving regions YHOLE.

The power gating switch PGS may be connected to each transistor, among a plurality of transistors in the function block 200, and may be designed to have a higher driving capability than other devices to drive the plurality of transistors. As such, a gate terminal of the power gating switch PGS may be designed to have a large line width compared to other devices and may necessarily have a high capacitance.

As the activation and deactivation of the function block 200 is repeated, a voltage level of the third driving voltage VN1 may be increased to be higher than a target voltage level as the charge of a gate terminal of the power gating switch PGS is discharged in the process of turning the power gating switch PGS off. If the voltage level of the third driving voltage VN1 is increased to be higher than the target voltage level, an operational error may occur in the function block 200, or the power consumption of the negative voltage generation circuits 1100 and 1400 may increase in order to bring the voltage level of the third driving voltage VN1 to the target voltage level.

However, an embodiment of the present disclosure may fully discharge a voltage level of the gate of the power gating switch PGS to a voltage level of the second driving voltage VSS according to the first control signal PCTRL1 and the second control signal PCTRL2 and then may apply the third driving voltage VN1, which has a lower voltage level than the second driving voltage VSS, to the gate terminal of the power gating switch PGS according to the third control signal PCTRL3. This may prevent an operation error of the function block 200 from occurring and may prevent an increase in power consumption by the negative voltage generation circuits 1100 and 1400. In addition, a voltage level of the third driving voltage VN1 may be kept stable, thereby minimizing leakage current in the function block 200.

A person skilled in the art to which the present disclosure pertains can understand that the present disclosure may be carried out in other specific forms without changing its technical spirit or essential features. Therefore, it should be understood that the embodiments described above are illustrative in all aspects, not limitative. The scope of the present disclosure is defined by the claims to be described below rather than the detailed description, and it should be construed that the meaning and scope of the claims and all changes or modified forms derived from the equivalent concept thereof are included in the scope of the present disclosure.

What is claimed is:

1. A power gating circuit, comprising:
a power gating switch configured to be coupled to a function block and configured to operate in response to a voltage level of a first node; and
a switching circuit configured to turn off the power gating switch by:
discharging the first node to a second driving voltage level during a first time period after blocking a first driving voltage from being applied to the first node in accordance with a plurality of control signals; and
applying a third driving voltage to the first node during a second time period after the first time period.

2. The power gating circuit of claim 1, further comprising a control circuit configured to generate the plurality of control signals in accordance with a preliminary control signal.

3. The power gating circuit of claim 2, wherein the preliminary control signal is activated in response to a read command and a write command, respectively, and deactivated after terminating a read operation in response to the read command and after terminating a write operation in response to the write command.

4. The power gating circuit of claim 1, wherein the first driving voltage is a positive voltage, and
wherein the third driving voltage is at a lower voltage level than the second driving voltage.

5. The power gating circuit of claim 4, wherein the switching circuit is configured to block the first driving voltage from being applied to the first node in accordance with a first control signal, among the plurality of control signals, configured to transition the first node to the second driving voltage level during the first time period in accordance with a second control signal, among the plurality of control signals, and configured to apply the third driving voltage to the first node during the second time period in accordance with a third control signal, among the plurality of control signals.

6. The power gating circuit of claim 1, wherein the switching circuit comprises:
a first transistor configured to receive the first driving voltage at its source terminal, couple its drain terminal to the first node, and operate according to a first control signal, among the plurality of control signals;
a second transistor configured to receive the second driving voltage at its source terminal, couple its drain terminal to the first node, and operate according to a second control signal, among the plurality of control signals; and
a third transistor configured to receive the third driving voltage at its source terminal, couple its drain terminal to the drain terminal of the first transistor, and operate according to a third control signal, among the plurality of control signals.

7. The power gating circuit of claim 6, wherein the switching circuit further comprises:
a first logic gate configured to invert the first control signal;
a second logic gate configured to invert an output of the first logic gate and output a first inverted signal to a gate terminal of the first transistor; and
a third logic gate configured to invert the third control signal and output a second inverted signal to a gate terminal of the second transistor.

8. The power gating circuit of claim 7, wherein the first logic gate and the second logic gate are configured to receive a fourth driving voltage having a higher voltage level than the first driving voltage as a power source for a pull-up operation and configured to receive the third driving voltage as a power source for a pull-down operation.

9. A power gating circuit, comprising:
a power gating switch configured to be coupled to a function block and configured to operate in response to a voltage level of a first node;
a first transistor configured to receive a first driving voltage at its source terminal, couple its drain terminal to the first node, and operate according to a first control signal;
a second transistor configured to receive a second driving voltage at its source terminal, couple its drain terminal to the first node, and operate according to a second control signal; and
a third transistor configured to receive a third driving voltage at its source terminal, couple its drain terminal to the drain terminal of the first transistor, and operate according to a third control signal.

10. The power gating circuit of claim 9, further comprising:
a first logic gate configured to invert the first control signal;
a second logic gate configured to invert an output of the first logic gate and output a first inverted signal to a gate terminal of the first transistor; and
a third logic gate configured to invert the third control signal and output a second inverted signal to a gate terminal of the second transistor.

11. The power gating circuit of claim 10, wherein the first logic gate and the second logic gate are configured to receive a fourth driving voltage having a higher voltage level than the first driving voltage as a power source for a pull-up operation and configured to receive the third driving voltage as a power source for a pull-down operation.

12. The power gating circuit of claim 9, further comprising a control circuit configured to generate the first control signal, the second control signal, and the third control signal in accordance with a preliminary control signal.

13. The power gating circuit of claim 12, wherein the preliminary control signal is activated in response to a read command and a write command, respectively, and deactivated after terminating a read operation in response to the read command and after terminating a write operation in response to the write command.

14. A semiconductor apparatus, comprising:
a plurality of memory banks;
a plurality of column driving regions configured to be coupled to the plurality of memory banks, configured to receive a first driving voltage and a third driving voltage, and configured to include circuits associated with column operations of each of the plurality of memory banks; and
a voltage generation circuit configured to generate the third driving voltage in response to a power source that is external to the semiconductor apparatus, and configured to provide the third driving voltage to each of the plurality of column driving regions,
wherein each of the plurality of column driving regions includes at least one function block and a power gating circuit coupled to the function block, and
wherein the power gating circuit includes: a power gating switch configured to be coupled to the function block and configured to operate in response to a voltage level of a first node; and a switching circuit configured to turn off the power gating switch by:
discharging the first node to a second driving voltage level during a first time period after blocking the first driving voltage from being applied to the first node in accordance with a plurality of control signals; and
applying the third driving voltage to the first node during a second time period after the first time period.

15. The semiconductor apparatus of claim 14, further comprising a control circuit configured to generate the plurality of control signals in accordance with a preliminary control signal.

16. The semiconductor apparatus of claim 15, wherein the preliminary control signal is activated in response to a read command and a write command, respectively, and deactivated after terminating a read operation in response to the read command and after terminating a write operation in response to the write command.

17. The semiconductor apparatus of claim 14, wherein the first driving voltage is a positive voltage, and
wherein the third driving voltage is at a lower voltage level than the second driving voltage.

18. The semiconductor apparatus of claim 14, wherein the switching circuit is configured to block the first driving voltage from being applied to the first node in accordance with a first control signal, among the plurality of control signals, configured to transition the first node to the second driving voltage level during the first time period in accordance with a second control signal, among the plurality of control signals, and configured to apply the third driving voltage to the first node during the second time period in accordance with a third control signal, among the plurality of control signals.

19. The semiconductor apparatus of claim 14, wherein the switching circuit comprises:
a first transistor configured to receive the first driving voltage at its source terminal, couple its drain terminal to the first node, and operate according to a first control signal, among the plurality of control signals;
a second transistor configured to receive the second driving voltage at its source terminal, couple its drain terminal to the first node, and operate according to a second control signal, among the plurality of control signals; and
a third transistor configured to receive the third driving voltage at its source terminal, couple its drain terminal to the drain terminal of the first transistor, and operate according to a third control signal, among the plurality of control signals.

20. The semiconductor apparatus of claim 19, wherein the switching circuit further comprises:
a first logic gate configured to invert the first control signal;
a second logic gate configured to invert an output of the first logic gate and output a first inverted signal to a gate terminal of the first transistor; and
a third logic gate configured to invert the third control signal and output a second inverted signal to a gate terminal of the second transistor.

21. The semiconductor apparatus of claim 20, wherein the first logic gate and the second logic gate are configured to receive a fourth driving voltage having a higher level relative to the first driving voltage as a power source for pull-up operation and configured to receive the third driving voltage as a power source for pull-down operation.
